(19) United States
(12) Patent Application Publication
(10) Pub. No.: US 2002/0110956 A1
(43) Pub. Date: Aug. 15, 2002

(54) Chip lead frames

(76) Inventors: Takashi Kumamoto, Tsukuba-shi (JP); Kinya Ichikawa, Tsukuba-shi (JP)

Correspondence Address: FISH & RICHARDSON, PC, 4350 LA JOLLA VILLAGE DRIVE, SUITE 500, SAN DIEGO, CA, 92122, US

(21) Appl. No.: 09/878,123

(22) Filed: Jun. 8, 2001

Related U.S. Application Data
(63) Continuation-in-part of application No. 09/741,535, filed on Dec. 19, 2000.

(51) Int. Cl. H01L 23/495; H01L 23/34; H01L 29/40; H01L 21/44; H01L 21/48; H01L 21/50

(52) U.S. Cl. 438/108; 257/666; 257/778; 257/723; 257/704; 257/738; 257/710; 257/737; 438/123; 438/613; 438/111

(57) ABSTRACT

Chip lead frames are made by disposing a die having terminals on a substrate surface to form a cavity between the die and the substrate and contacts between the terminals and the substrate. A compound is applied to the surface such that the compound enters that cavity and forms a layer on the upper substrate surface. The layer can impart sufficient rigidity to the assembly that the substrate can be etched to produce a lead frame. Also disclosed are devices that include a die, a lead frame, and a continuous network that can form a layer on the lead frame and fill the cavity between the die and the lead frame.

### CROSS-REFERENCE TO RELATED APPLICATIONS

This application claims priority under 35 USC is a continuation-in-part of U.S. patent application Ser. No. 09/741,535, filed on Dec. 29, 2000, the entire contents of which are hereby incorporated by reference.

### BACKGROUND

This invention relates to chip lead frames.

A semiconductor chip can include millions of transistor circuits, each smaller than a micron, and multiple connections between the chip and external elements.

Referring to FIG. 1A, a so-called flip chip configuration facilitates a compact assembly, reduced footprint size on boards, and shorter and more numerous input-output (I/O) connections with improved electrical and thermal performance. A flip chip typically includes a die 101 with solder bumps 110 that are interconnected conductive elements to a substrate 114.

One method of electrically connecting a flip chip utilizes controlled-collapse chip connection technology (C4). First, solder bumps 110 are applied to pads on the active side of the die 101, the substrate 114 or both. Next, the solder bumps 110 are melted and permitted to flow, ensuring that the bumps are fully wetted to the corresponding pads on the die 101 or substrate 114. A tacky flux is typically applied to one or both of the surfaces to be joined. The flux-bearing surfaces of the die 101 and substrate 114 are then place in contact with each other in general alignment. A reflow is performed by heating the die 101 and substrate package to or above the solder's melting point. The solder on the chip and the substrate combine and the surface tension of the molten solder causes the corresponding pads to self-align with each other.

The joined package is then cooled to solidify the solder. The resulting height of the solder interconnects is determined based on a balance between the surface tension of the molten solder columns and the weight of the chip. Any flux or flux residue is removed from the die 101 and substrate 114 combination in a defluxing operation.

Finally, an epoxy underfill 116 is applied between the bottom surface of the die 101 and the top surface of the substrate 114, surrounding and supporting the solder columns. The reliability and fatigue resistance of the die-substrate solder connection is increased significantly. The underfill 116 acts to carry a significant portion of the thermal loads induced by coefficient of thermal expansion (CTE) differences between the chip and substrate, rather than having all the thermal load transferred through the solder columns. The underfill 116 can also electrically insulate the solder columns from one another.

For some integrated circuit applications, it is desirable to utilize as thin a substrate or film as possible to maximize the electrical performance of the resulting packaged chip. Typically, thin substrates or films include a polymeric material and are 0.05 to 0.5 mm thick. A thin substrate's shorter vias help reduce loop inductance within the substrate. These thin substrates are very flexible and can cause difficulties for attaching solder balls or pins. In unreinforced form they are susceptible to damage during installation and removal operation. One current practice is to bond rigid blocks 111 of a suitable material to the periphery of the substrate using an adhesive layer 112.

The attached rigid block 111 stiffens the entire package. Referring also to FIG. 1B, support bars 109 from the rigid block 111 can be used to strengthen individual elements, such as a land grid array (LGA) pad 230 that is attached to a flip chip pad 206 by a routing lead 204.

It is also known to run the epoxy adhesive up the sides of the die 101 to form an epoxy fillet that reinforces the die (see, e.g., U.S. Pat. No. 6,049,124).

### DESCRIPTION OF DRAWINGS

FIGS. 1A and 1B are schematics of a conventional flip chip configuration.

FIG. 2 is a schematic of a first process of packaging a die 101 and substrate 105.

FIG. 3 is a sequence of cross sections and schematics for a second process of packaging a die 101 and substrate 105.

FIG. 4 is a schematic of a process of packaging dies 101. The process includes dicing the substrate 105.

FIG. 5 is a flow chart for a process of packaging a die 101.

FIG. 6 is a schematic of a process of packaging a die using a half-etched lead frame 105.

FIG. 7 is a schematic of a routing lead and pad.

FIG. 8 is a schematic of a ball grid array.

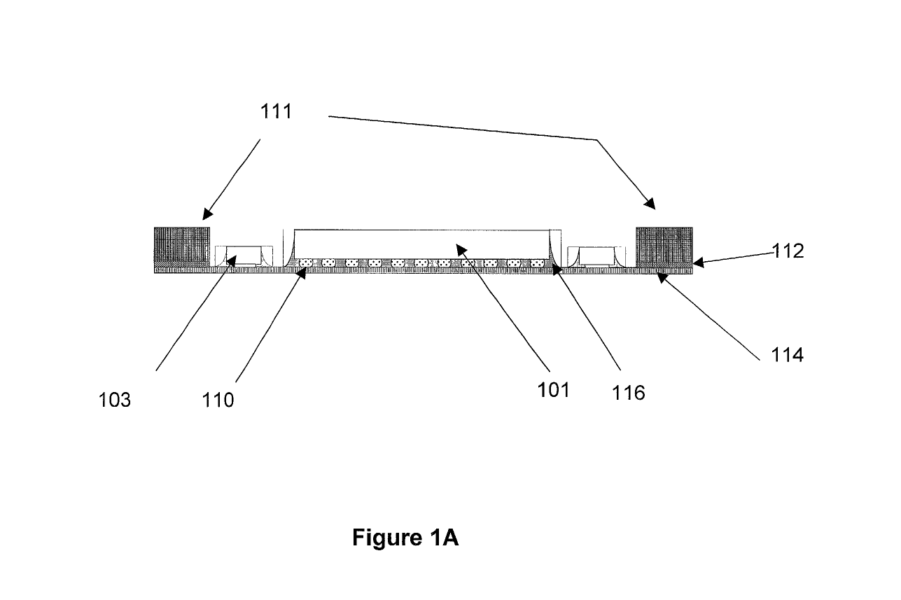

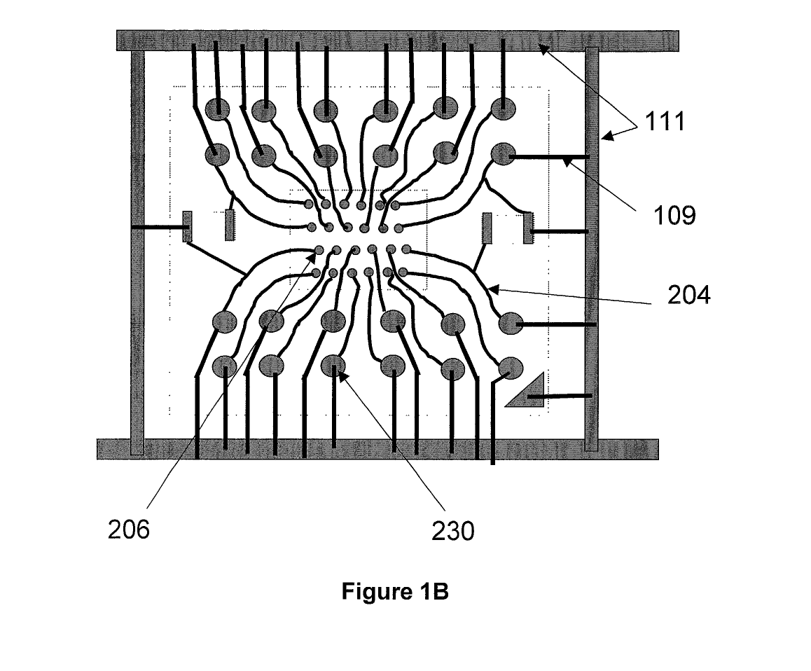

### DETAILED DESCRIPTION

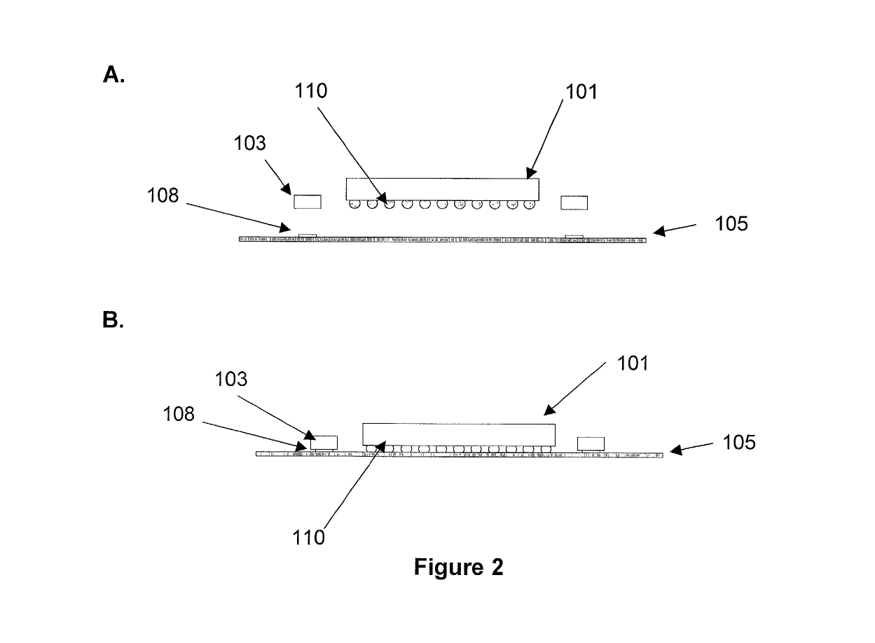

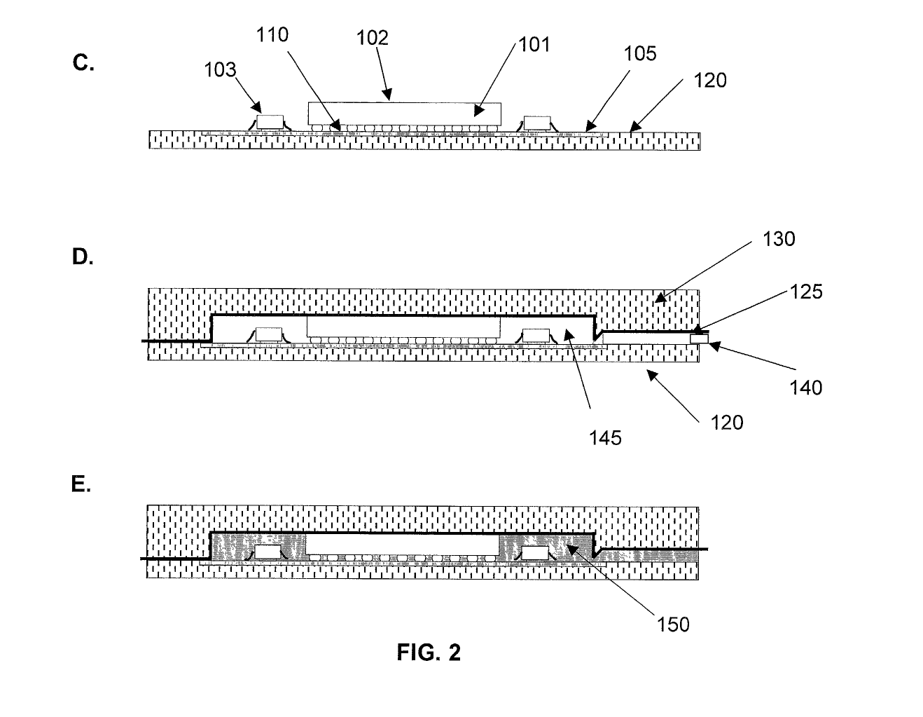

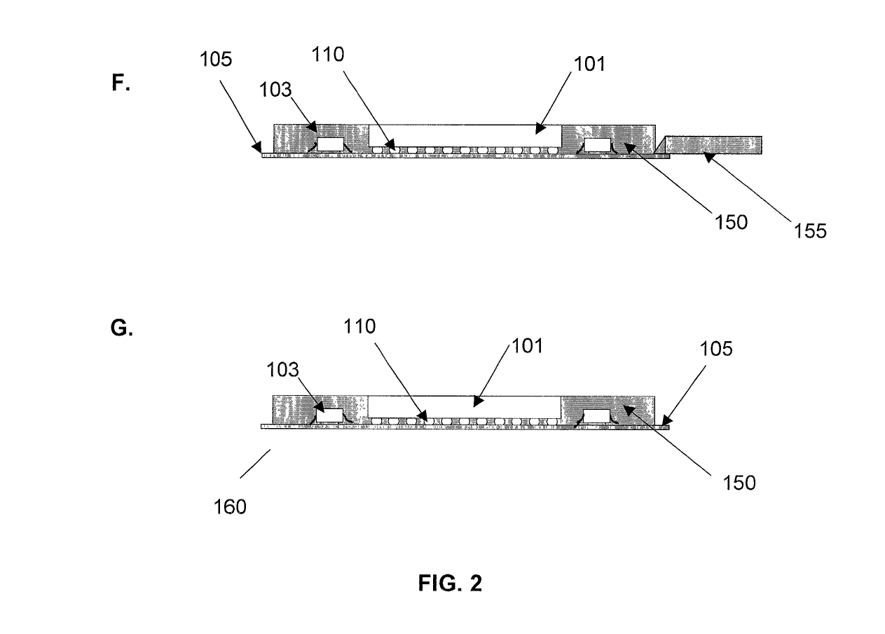

Referring to the example in FIGS. 2A to 2G, a die 101 is attached to a substrate 105, and then packaged to form an assembly 160 (FIG. 2G).

Referring to FIG. 2A, the die 101 is first oriented with respect to the substrate 105. The die 101 can be a chip or silicon wafer that bears an integrated circuit. The substrate 105 can be a conductive material such as copper. For example, the substrate 105 can be a continuous copper, or other conductive, foil. The copper foil can include at least about 40%, 50%, 70%, 90%, or 99% copper by weight. The low electrical resistance of copper improves the performance of the fabricated flip chip assembly.

The substrate can be less than about 22, 20, 18, or 16 μm thick.

The substrate 105 can have insulative pads 108 for mounting passive components 103 such as decoupling capacitors that lower the power supply loop inductance.

The die 101 includes solder bumps 110 for forming interconnects with the substrate 105. Examples of solder compositions include high temperature bump (e.g., 97% Pb and 3% Sn), eutectic bump (63% Pb and 37% Sn), stud bump (e.g., 100% Au), and conductive epoxies. Bumps can be formed by combinations of the above, for example, as a high temperature bump which is plated with a eutectic bump.

The bumps 110 can be arranged in a regular array on the die lower surface. For example, the bumps can have a pitch of about 11 mils (279.4 μm).

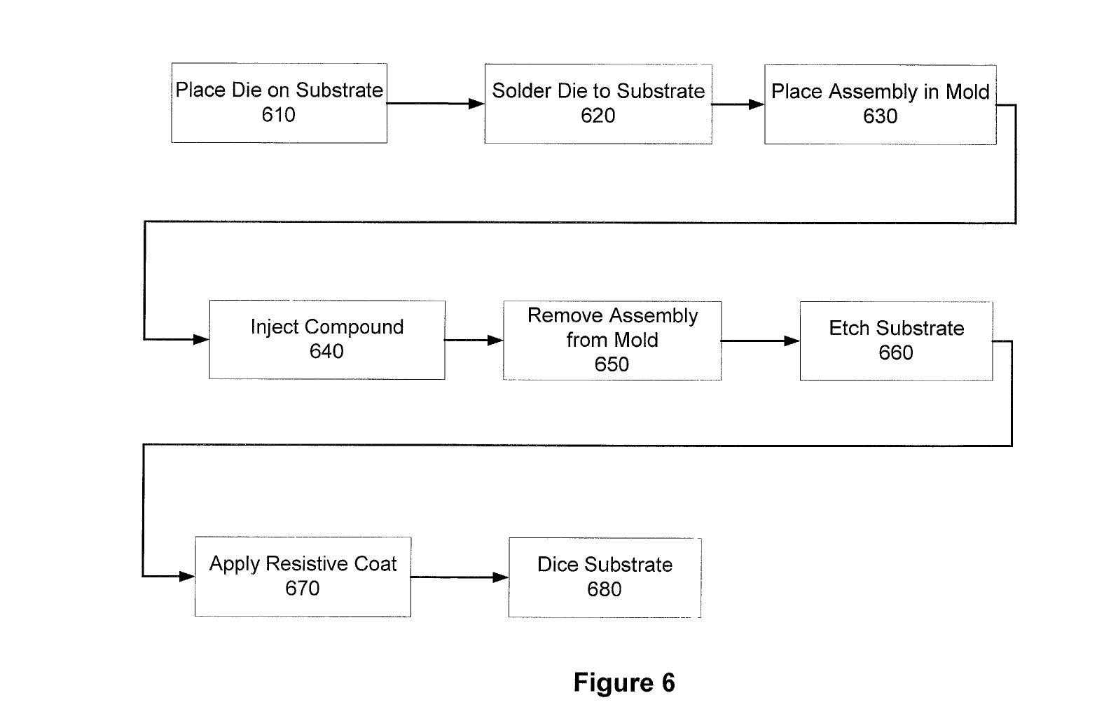

Referring to FIG. 2B and also to FIG. 6, the die 101 is disposed 610 on the substrate 105 such that the bumps 110 contact the substrate. Heat is used to attach 620 the solder bumps 110 to the substrate 105.

In some embodiments, thermo-compression bonding is used to locally heat the die 101 with a pulse of heat. For example, the bonding process can apply 2 gf/bump and a heat pulse of 230° C. for 3 second. Such a process can obviate the need for a flip chip pad that has solder resist dams positioned to receive the solder bumps 110.

In other embodiments, a reflow furnace is used to melt the solder bumps and bond them to the substrate 105. The substrate can include solder resist dams to contain the reflowing solder of each bump. See below for a description of the use of an interposer layer 300 to form solder resist dams.

After attachment of the die, the die 101 lower surface and the substrate upper surface form a gap 115 which is spanned by contacts formed from the solder bumps 110. The gap can, for example, be less than about 120, 100, 80, or 50 μm.

Referring to FIGS. 2C and 2D, the substrate 105 is placed 630 between a bottom mold 120 and a top mold 130. The mold top 130 and/or bottom 120 can include any suitable material, including various metals, plastics, ceramics, and composites. The mold can have sufficient rigidity that it retains its form while a composition is being injected into the mold cavity 145 under pressure.

The top mold 130 can bear a release film 125. The release film 125 can be a heat resistive film that separates the die 101 upper surface 102 from the top mold 130. The release film 125 can be used to prevent flashes to the die 101 upper surface 102 in order to maintain the upper surface 102 free of the epoxy. One exemplary release film is provide by Film Assisted Molding Equipment (Fame®)from Apic Yamada Corp., Japan. The release film can include fluorocarbon-based polymers and have a thickness of 0.5 to 5 mils.

The mold can include small air vents, e.g., opposite the runner 140, to allow air to escape from the cavity 145 when displaced by the injected composition.

Referring to FIG. 2E, a composition which can form a polymer is injected 640 into the runner 140 that connects to the mold cavity 145. The composition can be delivered under pressure, e.g., in a hot plastic state from an auxiliary chamber through runners and gates into the cavity 145. After injection, the composition can be allowed to set and form a polymer network 150 that extends between the cavity between the die 101 and the substrate 105. The setting process can include incubation under curing conditions.

By forming a polymer network that underfills the die 101 and extends to all regions of the substrate that are not covered by the die or another component (such as the passive components 103), the assembly 160 is rigidified and strengthened, even though it lacks a rigid support member (such as the rigid frame 111).

The extent of the polymer network can be varied, for example, by appropriate mold (120 and 130) design. Accordingly, in some embodiments, the polymer network can form layers of varying heights (i.e., in a direction normal to the substrate 105), e.g., up to the lower die surface, to the upper die surface, or 205, 40%, 50%, 60%, or 80% between the two.

Similarly, the extent of the polymer network along the plane of the substrate 105 can vary, again, by appropriate mold design. Accordingly, in some embodiments, the polymer network extends at least to a passive component 103 or other component attached to the substrate 105, to another die 101 disposed on the same substrate 105, or to the perimeter of the substrate 105. The polymer network can (additionally or alternatively) extends a distance (parallel to plane of the substrate 105) away from the die perimeter that is at least the height of the die 101, i.e. the distance from the die lower surface that opposes the substrate 105 to the die upper surface.

A variety of compositions can be used to form the underfill and rigidified assembly. The compound can be a resin, or another compound that forms a polymer. The polymer is typically non-conductive. A continuous rigid network is the contiguous structure formed by setting the compound. The structure imparts rigidity to the substrate 105 (or lead frame 210, as described below).

Resins include crystalline resins, and multi-functional-type resins. Other resins, such as BMI's, polyesters, and thermoplastics, may be utilized as appropriate.

In some embodiments, the compound is an epoxy, such as glass-filled epoxy. The epoxy resin utilized can have high strength and good thermal properties, including resistance to the high temperatures that can be generated by an integrated chip during operation. Additionally, epoxy in the uncured liquid state can have relatively low viscosities to facilitate injection into the space between the chip and substrate surfaces. For example, the epoxy can have a melt viscosity of less than about 20, 15, 12, 10, or 8 Pa·s at 165° C.

Table 1 lists some of the properties of an exemplary epoxy formulation. Such properties are non-limiting and may be present alone or in combinations with other properties.

In general, the difference in the coefficient of thermal expansion (CTE) between virgin unfilled epoxy and either a silicon chip or a reinforced plastic substrate will be significant. Given the wide range of operating temperatures that a flip chip package may experience, it is desirable to tailor the CTE's of the joined materials to be as close as possible, thereby minimizing any induced thermal stresses. Conversely, too much filler could cause the viscosity of the epoxy formulation to increase to a point where it is resistant to flow in the gap between the top of the chip 110 and the corresponding surface of the substrate 120. Additionally, if the filler has a higher modulus than the virgin epoxy, it acts to increase the stiffness of the cured epoxy formulation, which results in greater rigidity for the resulting chip package. Accordingly, a filled epoxy resin comprising about 80% by weight silica microspheres is believed to be the ideal formulation.

TABLE 1

| Filler material | Silica |
|---|---|
| Filler shape | All Spherical |
| Filler content | 80 wt % |
| Mean particle size | 4 μm |
| Maximum particle size | 12 μm |
| Curing condition | 165° C./120 sec |
| Spiral flow | 180° cm at 165° C./120 sec. |
| | 6.9 N/mm2 |
| Gelation time | 30 sec at 165° C. |
| Hot hardness | 85 at 165° C./120 sec |
| Melt viscosity | 10 Pas at 165° C. |
| Glass transition | 145° C. |
| temperature | |
| CTE below Tg | 14 ppm |
| CTE above Tg | 56 ppm |
| Specific gravity | 1.88 at 25° C. |
| Thermal conductivity | 0.63 W/m*C |
| Flexural modulus | 13700 N/mm² at 25° C. |
| Flexural strength | 120 N/mm² at 25° C. |
| Volume resistivity | 1.00 E+14 ohm*m 25° C. |
| Water absorption | 0.5% |

It is also desirable to have an epoxy formulation that cures relatively quickly at an elevated temperature so that ship packages can be fabricated at production rates, but that has a relatively long pot life at room temperature or even slightly elevated temperatures so that the mixed epoxy and catalyst does not cure in the supply lines before being injected into the mold. The preferred resin has a cure profile of approximately 120 seconds at 165° C. Depending on the properties of an alternative resin formulation, different cure profiles may be specified that provide suitable results. It is also contemplated that certain thermoplastic resins may be utilized in the molding operation that do not have a cure temperature but rather melt at an elevated temperature and solidly when cooled.

Utilizing an epoxy resin of the type and formulation specified in Table 1, the molding process would proceed as follows. First, the mold is either heated to 165° C. with the incomplete chip package contained therein, or the mold is maintained at 165° C. and the incomplete package is inserted therein. Next, the epoxy resin is injected through runner 140 in the mold at a pressure or around 1-5 MPa. The resin may be preheated to an intermediate temperature to lower the viscosity of the resin and facilitate the resin transfer modeling process. Once the proper amount of epoxy is injected into the mold cavity, the mold is held at 165° C. for at least 120 seconds to fully cure the epoxy.

Referring to FIGS. 2F and 6, after cure, the mold is separated and the assembly 160, as depicted in FIG. 2F, is removed 650. Typically, the molded flip chip package will be removed while the mold is hot so that the mold may immediate be re-used to fabricate another package; however it is conceivable that the mold may be permitted to cure before removing the molded flip.

Referring to FIG. 2G, the assembly 160 is trimmed to provide an epoxy-surrounded and underfilled die 101 on the conductive substrate 105.

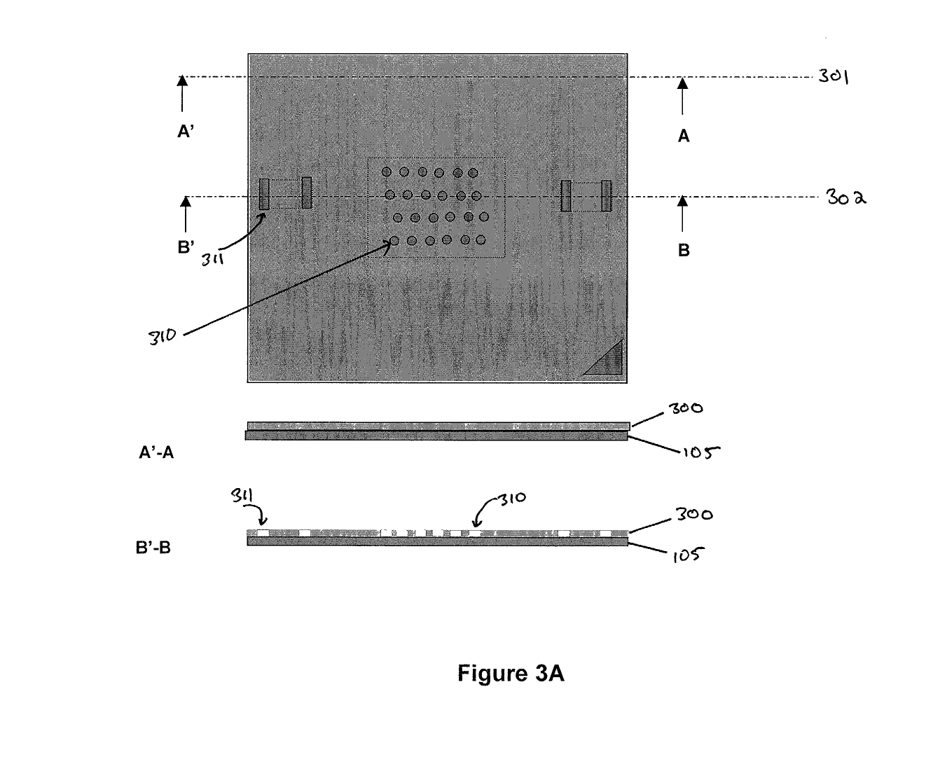

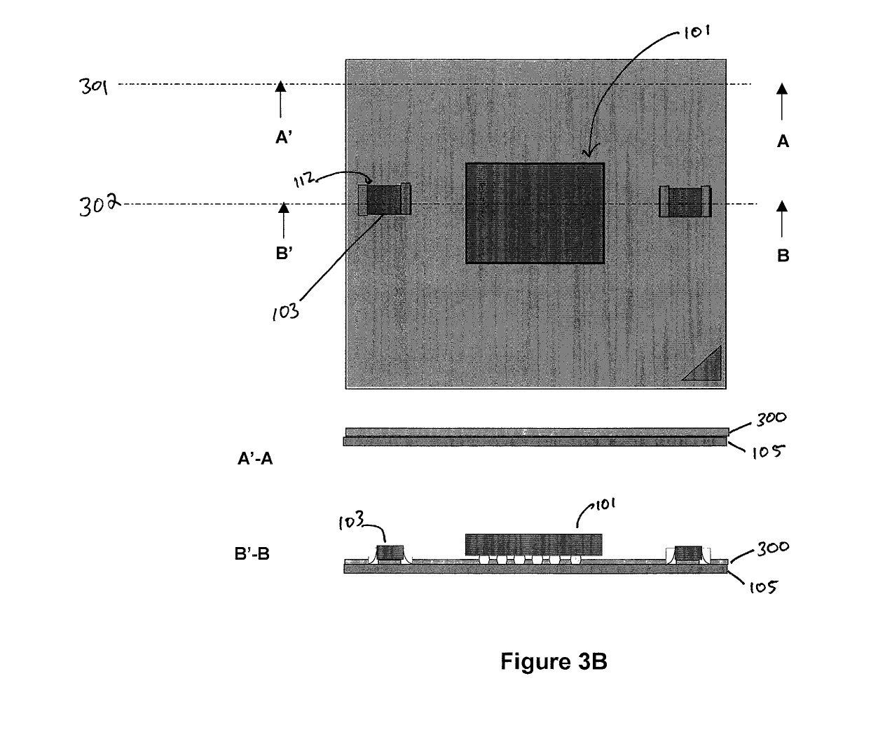

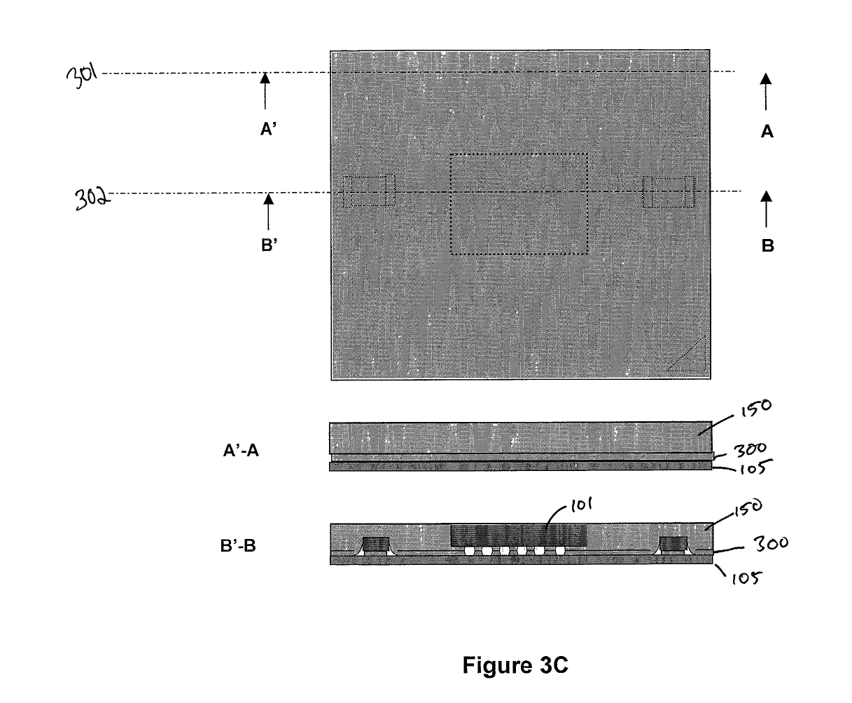

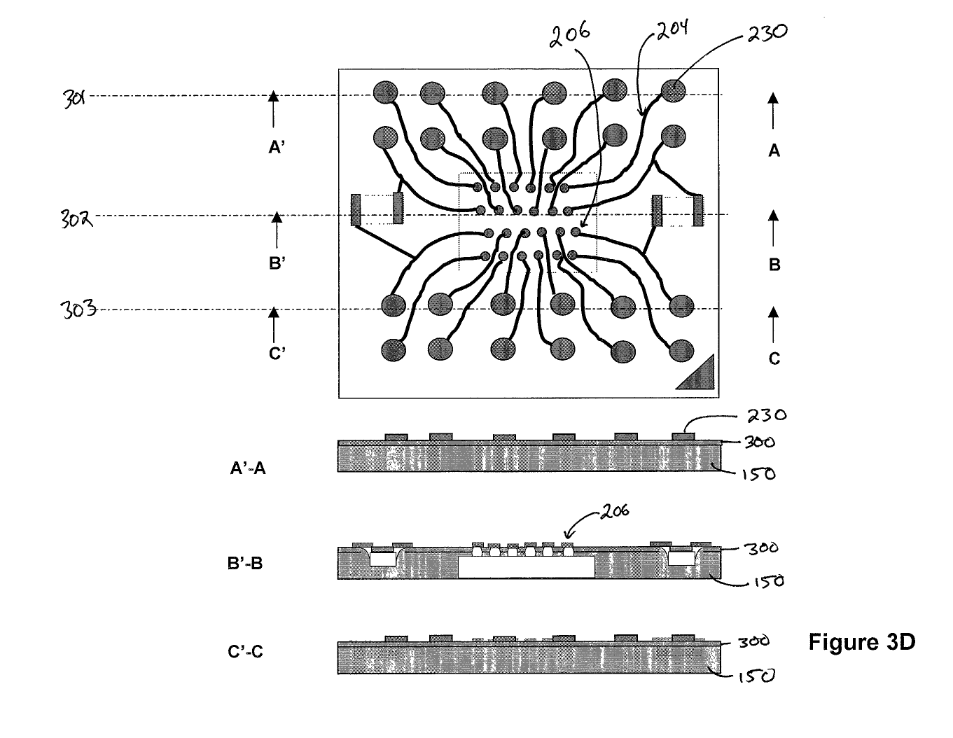

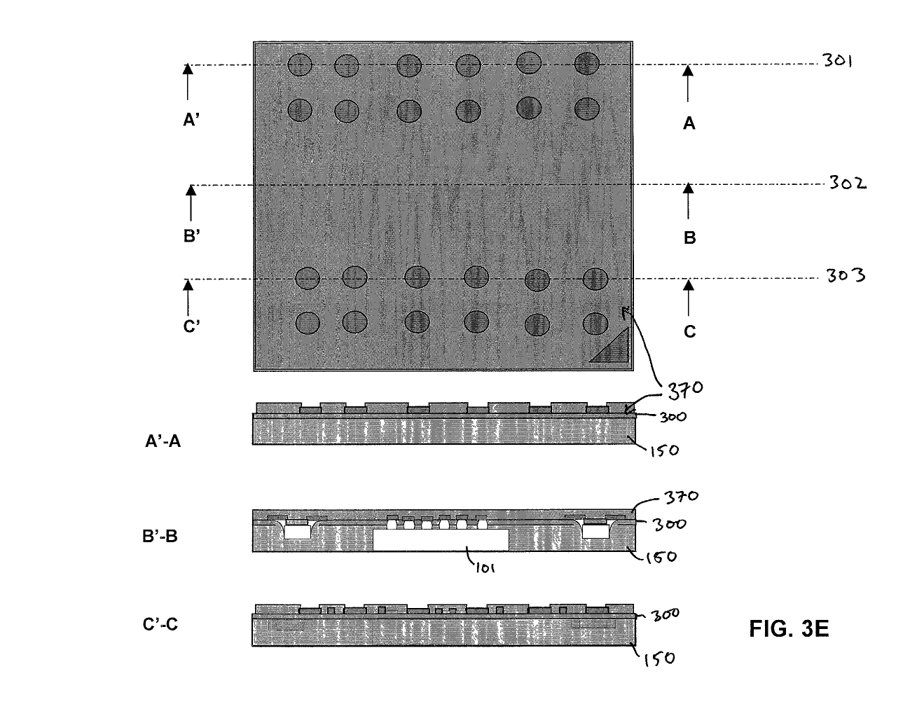

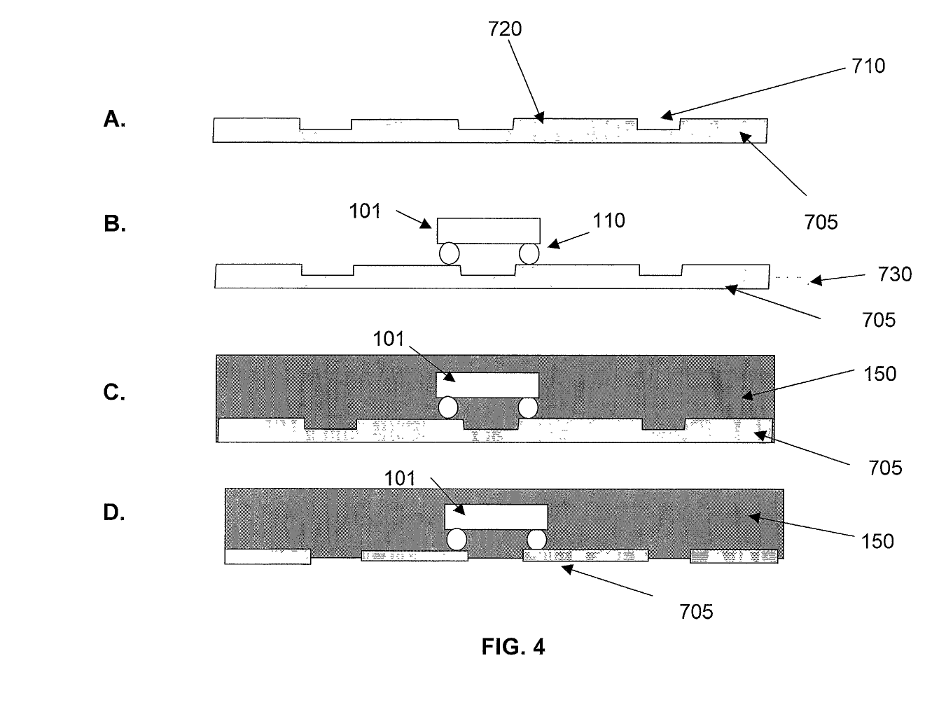

Referring to FIGS. 3A to 3E, a variation of the above process is used for fabrication of the flip chip-substrate assembly 160. A thin substrate 105 is coated with a insulative resist layer 300. The insulative layer is etched or otherwise modified to excise regions 310 that can accept solder balls or other contacts from components. The insulative layer 300 has high electrical resistance, i.e., it is formed from a non-conductive material.

Referring also to FIG. 3B, a die 101 is placed on the substrate 105 such that the solder balls 110 on the die 101 are positioned in the excised acceptor regions 310. When appropriately heated the solder balls reflow and form stable electrical contacts with the substrate 105. Similarly passive components 103, such as a capacitor, are also connected to the substrate by solder contacts 112.

Referring to FIG. 3C, as described above, the assembly formed by the die 101, passive components 103 and substrate 105 are surrounded in a mold and coated 640 with an epoxy layer 150 that forms a continuous rigid supporting structure 150.

If a gap is formed between the insulative layer 300 and the die 101 lower surface, then the structure formed by the epoxy layer can fill the gap.

After forming the epoxy casing 150 as depicted in both FIGS. 2G and 3D, the conductive substrate 105 is modified by etching 660 to fabricate a lead frame 210. Etching 660 is not limited to chemical etching. For example, the etching 660 can be done by UV- or CO₂-high powered laser abrasion, photolithographic, or traditional copper etching processes.

Referring to FIG. 3, the etching 660 leaves conductive paths 204 that connect, for example, each die interconnect 110 with a terminus 230.

The termini 230 can be arranged for convenient interfacing with any of a variety of chip interface formats, such as land grid arrays (LGA), ball grid arrays (BGA), pin grid arrays (PGA), printed circuit boards (PCB), or mother boards.

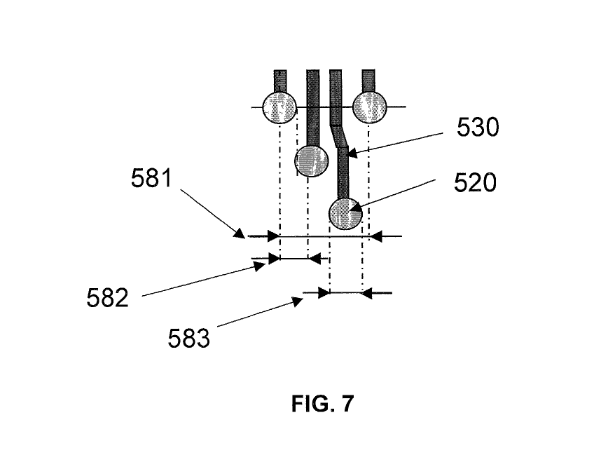

Referring to FIG. 7, the rigidity and support provided by the epoxy encasement 150 not only allows the use of thin substrates 105, but also high density of C4 pads 206 and routing leads 204. For example, the center to center distance 582 between two C4 pads 206 can be less than about 0.127 mm, e.g., about 0.12, 0.10, 0.09, 0.08, 0.083, 0.07 mm or less. In other words, the pitch 581 between a first C4 pad and a fourth adjacent C4 pad is less than about 0.35, 0.3, 0.27, 0.25, or 0.2 mm.

Subsequently, an insulative coating 370 is applied 670 to the etched substrate. The insulative compound can be the same or different from the epoxy compound used to form the epoxy casing and underfill. The insulative compound forms a resist coat 370 that guards against shorts between different conductive paths 204 of the lead frame formed from the substrate 105.

In another implementation, as depicted in FIG. 6A, a half-etched substrate 705 is used. For a substrate having a thickness of about 18 μm, half-etches 710 are created that are about 9 μm deep and that are backed by an underlayer 730 of the substrate 705. Referring to FIG. 6B, the die 101 is disposed on the half-etched substrate 705 such that the die bumps 110 form interconnects along ridges 720 of the half-etched substrate 705. Referring to FIG. 6C, the assembly is contacted with the polymer composition to form a network 150 that rigidities and strengthens the assembly. Referring to FIG. 6D, the bottom half or substrate underlayer 730 of the half-etched substrate 705 is then removed in order to fabricate the lead frame 210.

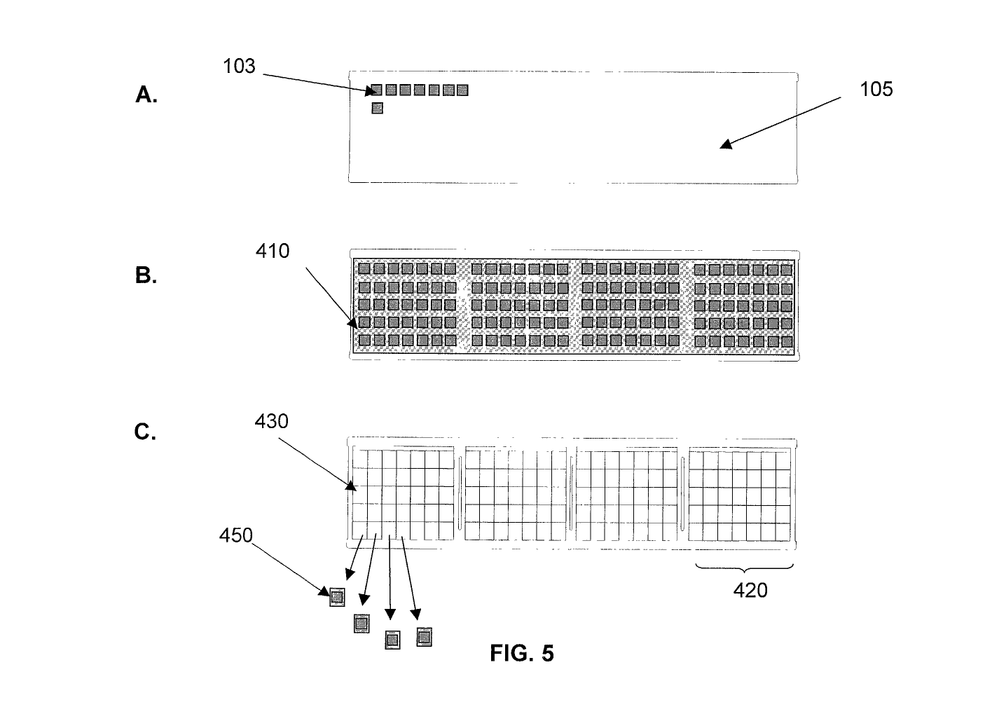

The steps 610 to 670 can be performed for multiple dies 101 in parallel, for example, as depicted in FIG. 5. Referring to FIG. 5A, multiple dies 101 are disposed on a panel that consists of the substrate 105. Reels, strips, and other formats of the substrate 105 can also be used.

Referring to FIG. 5B, the entire assembly is placed in the molds and encapsulated with epoxy to form the rigidified assembly 410. The lower surface of the substrate 105 can then be etched 660 to generate a lead frame. The etching can include exposing a display area 420 on the substrate lower surface 430 to light projected through a photolithographic mask.

Referring to FIG. 5C and also to FIG. 6, the substrate 105 is diced 680 to separate individual devices 450 that include a die 101 and its lead frame 210. Typically, after dicing, each individual device includes an encapsulating layer that extends to the perimeter of the device, i.e. of the lead frame 210.

The techniques described here are not limited to the examples described above.

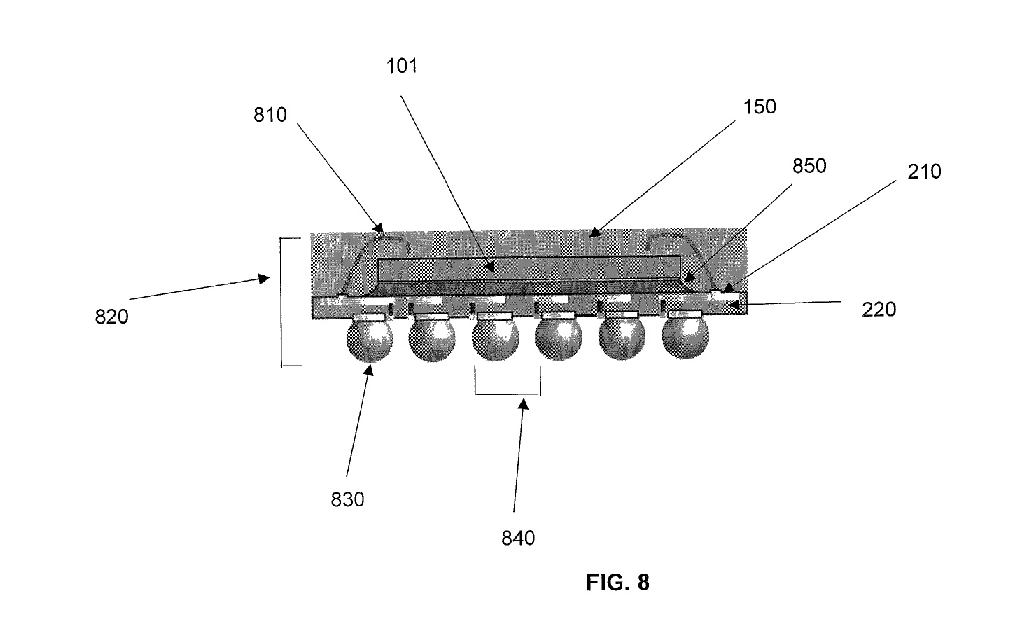

For example, the gap 115 can be filled with underfill prior to placement of the die 110 in the molds using the same composition or a different composition from the composition used to form the encapsulating network 150. By adjusting the shape of the molds, the encapsulating network 150 can be fabricated in a variety of configurations, e.g., extending at least to the lower die surface, at least to the upper die surface, or at least 25%, 50%, 75%, or 90% of the distance to the upper die surface from the lower die surface. In still another example, the encapsulating network 150 covers the upper die surface, as depicted in FIG. 8.

As described above, a lead frame produced by a method described here can be used in a variety of interface formats. Referring to FIG. 8, the lead frame 210 is connected to a BGA that includes multiple solder bumps 830 spaced with a pitch 840 of about 1 mm. The lead frame 210 can also include additional features such as a gold wire 810 that connects to the die 101. The assembly is encased in a polymer composition that covers the die upper surface 102, thus, forming an additional encapsulating layer 150. The assembly can have a height 820 of about 1.2 mm.

As depicted in FIG. 8, the gap between the lead frame 210 and the balls 830 is filled with an underfill composition 850 that differs from the encapsulating layer 150. The insulative coat 220 forms a resistive layer between the lead frame 210 and the solder balls 830.

Other implementations are within the scope of the claims.

What is claimed is:

1. A device comprising:
a lead frame having conductive leads and an insulative composition interposed between the leads;
a die having a lower die surface that overlies a first region of the lead frame, is connected by contacts to the lead frame, and is spaced by a gap from the first region; and
a polymer composition that forms a continuous network that forms a layer that extends at least above the lower die surface and covers regions of the lead frame surface that are outside the first region and are not occupied by any component.

2. The device of claim 1 further comprising an insulative layer that at least partially fills the gap and covers the first region.

3. The device of claim 1 in which the continuous network extends at least 50% of the distance to an upper die surface from the lower die surface.

4. The device of claim 3 in which the continuous network forms a layer covering the upper die surface.

5. The device of claim 1 in which the leads have a pitch of less than 0.10 mm.

6. A device comprising:
a conductive substrate;
a die having a lower die surface that opposes a first region of the substrate, is connected by contacts to the substrate, and is spaced by a gap from the first region; and
a polymer composition that forms a network on a region of the substrate that extends at least above the lower die surface, the layer imparting sufficient rigidity to the device to maintain integrity of the contacts during etching of the substrate in the absence of a supporting frame.

7. The device of claim 6 in which the conductive substrate comprises etches that are filled with a resistive composition.

8. The device of claim 6 in which the substrate comprises half etches.

9. The device of claim 6 in which the layer extends at least to the upper die surface

10. A device comprising:
a lead frame;
a die having a lower die surface that overlies, is connected by contacts to, and is spaced by a gap from a first region of the lead frame;
a peripheral component also connected to the lead frame at a location other than in the first region; and
a polymer composition
that extends in a direction normal to the lead frame at least above the lower die surface and extends along a surface of the lead frame from the die to the peripheral component.

11. The device of claim 10 further comprising an insulative layer that at least partially fills gap and covers the first region.

12. The device of claim 10 in which the layer extends to a perimeter of the lead frame.

13. A method comprising:
a) forming a gap between a die and a substrate to which the die is connected;
b) causing a compound to enter the gap and to form a layer on an upper surface of the substrate; and
c) setting the compound to generate a continuous, rigid network that extends within the gap and forms a layer surrounding the die perimeter.

14. The method of claim 13 in which the layer extends at least to the surface of the die that opposes the substrate.

15. The method of claim 13 in which the layer extends along the plane of the substrate a distance that is at least the distance from the die lower surface to the die upper surface.

16. The method of claim 13 in which the layer extends to the perimeter of the substrate.

17. The method of claim 13 in which the applying comprises (1) surrounding the die and the upper substrate surface using a mold to form a mold cavity; and (2) injecting the compound into the mold cavity.

18. The method of claim 17 in which a surface of the mold includes a film.

19. The method of claim 17 in which the compound is injected under a pressure of at least 1 MPa.

20. The method of claim 13 in which the compound comprises an epoxy.

21. The method of claim 13 further comprising etching the substrate to generate leads, each lead forming a conductive path from one of the contacts to a lead terminus.

22. The method of claim 21 further comprising applying an insulative composition that fills etched regions of the substrate.

23. A method comprising:
a) disposing a die having terminals on an upper substrate surface of a conductive substrate such that a cavity is formed between the die and the substrate and contacts are formed between the terminals and the conductive substrate; and
b) etching the conductive substrate to generate conductive leads.

24. The method of claim 23 in which the disposing comprises (1) applying a compound to the surface such that the compound forms a layer on the upper substrate surface, and (2) setting the compound to form a continuous network.

25. The method of claim 23 in which the substrate comprises half-etches that are backed by a substrate underlayer, and the etching comprises removing the substrate underlayer.

26. The method of claim 23 in which the disposing comprises disposing multiple dies, and the method further comprises dicing the etched conductive substrate.

27. The method of claim 24 in which the compound fills the cavity.

28. The method of claim 24 further comprising, prior to applying the compound to the surface, filling the cavity using an underfill composition.

29. The method of claim 23 in which the upper substrate surface is covered by an insulative layer that has excised regions adapted for receiving the terminals.

30. The method of claim 29 in which a gap is formed between the insulative layer the die, and the method further includes, prior to b), applying a compound to the surface of the insulative layer that opposes the die; filling the gap with the compound; and setting the compound to form a continuous polymer network.
